(19) United States
(12) Patent Application Publication
(10) Pub. No.: US 2012/0180839 A1
(43) Pub. Date: Jul. 19, 2012

(54) THERMO-ELECTRIC ENERGY CONVERTER HAVING A THREE-DIMENSIONAL MICRO-STRUCTURE, METHOD FOR PRODUCING THE ENERGY CONVERTER AND USE OF THE ENERGY CONVERTER

(76) Inventors: Harry Hedler, Germering (DE); Jörg Zapf, Munchen (DE)

(21) Appl. No.: 13/499,094

(22) PCT Filed: Sep. 20, 2010
(86) PCT No.: PCT/EP10/63791

§ 371 Date: Mar. 29, 2012

(30) Foreign Application Priority Data
Sep. 29, 2009 (DE) 10-2009-043-413.5

(51) Int. Cl. H01L 35/34; H01L 21/34; H01L 35/28

(52) U.S. Cl. 136/201; 136/200; 438/54; 257/E21.46

(57) ABSTRACT

A thermo-electric energy converter converts thermal energy into electric energy and vice-versa. A three-dimensional micro-structure has micro-columns with different micro-column materials. The micro-column materials have different Seebeck-coefficients (thermopower). The diameters of said micro-columns which are arranged parallel to each other are from 0.1 μm-200 μm. The micro-columns have, respectively, an aspect ratio between 20-1000. Also, the micro-columns are coupled together as thermo-pairs for building a thermo-voltage. In order to produce the micro-structure, a template has a three-dimensional template structure with column-like template cavities, essentially inverse to the micro-structure micro-column material is inserted in the cavities thus producing micro-columns, and the template material is at least partially removed.

### CROSS REFERENCE TO RELATED APPLICATIONS

This application is based on and hereby claims priority to International Application No. PCT/EP2010/063791 filed on Sep. 20, 2010 and German Application No. 10 2009 043 413.5 filed on Sep. 29, 2009, the contents of which are hereby incorporated by reference.

### BACKGROUND

The invention relates to a thermoelectric energy converter having a three-dimensional microstructure, a method for producing the energy converter and a use of the energy converter.

Thermoelectric energy converters are known that are based on the Seebeck effect. These energy converters are used as thermoelectric sensors. The main element of such an energy converter is a thermocouple having two thermocouple legs which are made of different thermocouple leg materials having a different thermopower (Seebeck coefficient).

The thermocouple of such a thermoelectric energy converter is embodied, for example, as a two-dimensional structure having a lateral construction. In this case the thermocouple legs of the thermocouple lie on a membrane in a planar arrangement. A hot sensor junction of the thermocouple legs is arranged on a center of the membrane, and a cold sensor junction of the thermocouple legs is arranged on a silicon frame supporting the membrane.

This two-dimensional structure occupies a large amount of space for a comparatively small thermoelectrically active sensor area.

### SUMMARY

One possible object is to provide a thermoelectric energy converter that occupies a smaller amount of space in comparison with the related art.

The inventors propose a thermoelectric energy converter for converting thermal energy and electrical energy from one form to the other using at least one thermocouple. The energy converter comprises at least one self-supporting, three-dimensional microstructure having a first microcolumn, which has a first microcolumn longitudinal extent, a first microcolumn diameter and at least one first microcolumn material having a first thermopower, and at least one second microcolumn, which has a second microcolumn longitudinal extent, a second microcolumn diameter and at least one second of microcolumn material having a second thermopower that is different compared with the first microcolumn material. The longitudinal extents of the microcolumns are here arranged substantially parallel to one another. The microcolumn diameters are selected from the range 0.1 μm to 200 μm. The microcolumns each have an aspect ratio in the range 20 to 1000. In addition, the microcolumns are coupled together as a thermocouple to build up a thermoelectric voltage. Preferably, the microcolumn diameters are selected from the range 0.3 μm to 200 μm.

A substantially parallel arrangement of the microcolumns means here that the alignment of the microcolumn longitudinal extents can deviate by up to 10°.

The microstructure preferably comprises a multiplicity of such thermocouples. The multiplicity of thermocouples is preferably connected together in series in this case, so that a sum of the thermoelectric voltages of the thermocouples produces substantially a total thermoelectric voltage of the multiplicity of thermocouples. In the case of absorbed thermal radiation, this enables an extremely high sensitivity of more than 1000 V per Watt of absorbed incident radiation.

The inventors also propose a method for producing a thermoelectric energy converter having the following steps: a) providing a template comprising template material, the template having a three-dimensional template structure that is substantially the inverse of the microstructure of the thermoelectric energy converter and comprises columnar template cavities, b) arranging the microcolumn materials in the columnar cavities so as to produce the microcolumns, and c) removing the template material at least partially.

The following additional steps are preferably carried out in order to arrange the microcolumn materials: d) introducing starting material for at least one of the microcolumn materials into the cavities, and e) converting the starting material for the microcolumn material into the microcolumn material.

The microstructure allows a third dimension to be used. This enables a significant reduction in the space occupied by the thermocouple of a thermoelectric energy converter compared with the related art. The microstructure makes it possible to arrange a large number of thermocouples on the minimum space. A thermoelectric energy converter is thereby produced which has a brush-like microstructure that has a three-dimensional construction and is composed of extremely thin microcolumns (filaments, pins) arranged (systematically) in the form of an array. The microstructure has a grid containing grid points. The grid points are formed by the microcolumns. In the related art there is no method for producing such a microstructure having a (filament) grid of less than 10 μm for a filament length of up to 1000 μm and more.

The thermoelectric energy converter is based on the Seebeck effect, where thermal energy is converted into electrical energy. The microcolumns are the thermocouple legs of the thermocouple. The thermoelectric energy converter, however, can also be operated in reverse using the Peltier effect. In this case electric current flows through the thermocouple. The thermal energy released in the process can be emitted to the environment. Depending on the situation, this results in heating or cooling of the environment.

A large number of materials are possible as the microcolumn materials, for instance metals, metal alloys, semi-metals and semiconducting compounds. In particular, the first microcolumn material and/or the second microcolumn material comprise(s) an element selected from the group bismuth, antimony, tellurium and lead. Each microcolumn material can be made of only one of the elements in each case. Alloys and compounds of these elements are also possible. Of these, bismuth telluride (Bi₂Te₃) must be mentioned in particular, which at room temperature is a very efficient thermocouple leg material. Other suitable materials include the following combinations: bismuth-antimony (BiSb), lead-tellurium (PbTe) or silicon-germanium (SiGe).

The fundamental idea for producing the microstructure involves providing, on the basis of a template (array, mold), a template structure (array structure) containing template cavities that is the inverse of the microstructure. The longitudinal extents of the template cavities are arranged substantially parallel to one another, and each template cavity has an aspect ratio in the range 20 to 1000 and a template cavity diameter in the range 0.1 μm to 200 μm. In addition, a spacing between the adjacent template cavities equals a microcolumn spacing of the microstructure. This production method allows the third dimension to be used to realize the thermoelectric energy converter.

The microcolumns are preferably arranged side by side. It is also possible, however, for the microcolumns to be arranged one above the other. In this case the microcolumns preferably stand in direct contact with one another. According to a particular embodiment, the microcolumns are therefore arranged together one above the other into a total microcolumn having a total longitudinal extent. The first microcolumn and the second microcolumn form segments of the total microcolumn.

The microcolumn longitudinal extent of at least one of the microcolumns, or the total microcolumn longitudinal extent of the total microcolumn, is preferably selected from the range 50 μm to 10 mm, and in particular from the range of 100 μm to 1 mm. In particular, the microcolumn longitudinal extents (filament lengths) of a multiplicity of microcolumns or of all the microcolumns are selected from the stated ranges. The microcolumns may also be equal in length. It is also possible that the microcolumns of the microstructure are of different lengths, i.e. have different microcolumn longitudinal extents.

As already mentioned, the microcolumns can be arranged one above the other. The microcolumns are preferably arranged side by side, however. According to a particular embodiment, the microcolumns are arranged side by side such that a microcolumn interstitial space results between the microcolumns that has a microcolumn spacing between the microcolumns selected from the range 0.3 μm to 100 μm. The small microcolumn diameters (lateral extents) of the microcolumns and the small microcolumn spacing between the microcolumns mean that the thermocouple of the thermoelectric energy converter occupies an extremely small amount of space.

With these small microcolumn spacings, at least one mechanism for thermally isolating the microcolumns from one another is preferably provided in the microcolumn interstitial space between the adjacent microcolumns. This prevents lateral heat exchange or lateral heat transfer across the microcolumn interstitial space. This mechanism can be a material having a low thermal conductivity. In particular, the thermal isolation mechanism is a vacuum having a gas pressure of less than 10⁻² mbar. In particular, the gas pressure equals less than 10⁻³ mbar. The microstructure containing the microcolumns is evacuated.

In a particular embodiment, the microstructure of the thermoelectric energy converter comprises at least one thermal coupling mechanism for coupling thermal energy into the thermocouple and/or for coupling thermal energy out of the thermocouple. In particular, the thermal coupling mechanism comprises a thermal functional layer for absorbing thermal energy in the form of absorbed thermal radiation and/or for emitting thermal energy in the form of emitted thermal radiation. The thermal functional layer absorbs electromagnetic radiation, for example visible light or infrared light. The thermal energy absorbed in the process is transferred to the thermocouple. Conversely, the energy released when current flows through the thermocouple can be emitted to the environment by the functional layer as electromagnetic radiation (emitted radiation).

It is also possible that the thermal coupling mechanism comprises a chemically sensitive coating. Certain chemical substances, for example certain gases, adsorb on this chemically sensitive coating. When such gas molecules are absorbed onto the chemically sensitive coating, thermal energy is released that can then be detected by the thermoelectric energy converter.

The microstructure is preferably arranged on a microstructure substrate. An organic or inorganic material can be a substrate material here. For example, the microstructure substrate is a silicon wafer. The substrate material is silicon.

According to a particular embodiment, a readout device (readout electronics, readout circuit) for reading out the thermoelectric voltage of the thermocouple and/or a drive device (drive electronics, drive circuit) for driving the thermocouple by an electrical drive voltage are present. In this case these devices or parts thereof can be arranged as SMD devices (surface mount devices) on the microstructure substrate. These devices or parts thereof are preferably integrated in the microstructure substrate, however. In a particular embodiment, the readout device and/or the drive device are therefore integrated into the microstructure substrate of the microstructure. A silicon wafer is preferably used for this purpose as the microstructure substrate. The readout device and/or the drive device are introduced into the silicon wafer as an ASIC (Application-Specific Integrated Circuit).

In an alternative embodiment, the readout device and/or the drive device are integrated into a circuit substrate that is different from the microstructure substrate. The devices are realized via a separate circuit substrate. SMD devices can likewise be provided in this case. The circuit substrate, however, is preferably also a silicon wafer. Again in this case, the devices can be integrated as ASICs. Furthermore, it is also possible that one part of the readout circuit is integrated in the microstructure substrate and another part of the readout circuit is integrated in the circuit substrate.

In the case that the readout device and/or the drive device are integrated in a separate circuit substrate, it is particularly advantageous to connect the microstructure substrate and the circuit substrate together via flip-chip technology. The electrical contacts required for the readout/drive are made in a space-saving manner by using flip-chip technology. This results in a compact design of the thermoelectric energy converter.

With regard to the method, a template containing silicon as the template material is used in particular. For example, the method is carried out using a silicon wafer. The silicon wafer acts as the template. Silicon is particularly well-suited to producing the columnar template cavities described above having the required aspect ratios. The PAECE (Photo-Assisted Electrochemical Etching) process is implemented for this purpose. This method starts with the forming of “etch pits” into the surface of the silicon wafer, for example by photolithography. This surface-patterned silicon wafer is exposed to an etching solution containing hydrofluoric acid. By the action of an electric field and exposure to light, the columnar template cavities are produced with extremely high structure accuracy from the “etch pits”.

In addition to producing the columnar template cavities, filling the template cavities is a further essential step. This is done, for example, by filling the template cavities with liquid microcolumn material as the starting material or with another liquid starting material for the microcolumn material. Next, in the template cavities, the liquid material is converted into the solid microcolumn material, and the microcolumns are formed.

For example, liquid metal as the starting material is introduced at a raised temperature into the template cavities. The temperature is then reduced. The liquid metal solidifies and the corresponding microcolumns are formed from the metal.

It is also possible that the template cavities act as micro-reactors. In this case liquid starting material is introduced into the template cavities. A subsequent chemical reaction results in the formation of the microcolumn material, and the microcolumns are produced.

After formation of the microcolumns, at least part of the template material is removed. This means that the microcolumns are partially or entirely exposed. If the microcolumns are only partially exposed, the rest of the template left behind can act as the microstructure substrate. It is also possible, however, to use a template having a microstructure substrate for the microstructure. Then, after complete removal of the template material, the microstructure is left on the microstructure substrate.

After removal of the template material, an above-described thermal functional layer containing suitable functional material can be arranged at the ends of the microcolumns. To do this, it is provided that the functional layer containing the functional material is arranged at the ends of at least some of the microcolumns.

A first microcolumn and a second microcolumn can be arranged one above the other to form a total microcolumn. The total microcolumn comprises two segments arranged along the total microcolumn longitudinal extent that contain microcolumn materials that differ from each other. The total microcolumn is composed of two segments (sub-segments) containing different microcolumn materials. This is achieved, for example, by the template cavities being partially filled first with the first microcolumn material. After forming the first microcolumns, the regions of the template cavities that remain empty are filled with the second microcolumn material. Subsequent conversion into the second microcolumn material produces a total microcolumn having a first segment containing the first microcolumn and having a second segment containing the second microcolumn. It is also possible that the template cavities are filled with the two microcolumn materials from different ends and are transformed into the respective microcolumn materials in a single joint process.

The first and second microcolumns are preferably not arranged one above the other but side by side. This results in a heterogeneous microstructure constructed from the different microcolumn materials. This microstructure can be produced, for example, by covering some of the template cavities during arrangement of one of the microcolumn materials. Then the covered template cavities are filled with a different microcolumn material. The microcolumn materials can again be converted simultaneously in a joint process into the corresponding microcolumns. This results in the microstructure containing microcolumns made of the different microcolumn materials. It is also possible, however, to make these microcolumns in a serial process. This means that the first microcolumn material is converted first before the previously covered template cavities are filled with the second microcolumn material, which is then converted. It is also possible to make the first microcolumn cavities first and fill them with the first microcolumn material before making the second microcolumn cavities and filling them with the second microcolumn material.

The inventors also propose using the thermoelectric energy converter for converting thermal energy and electrical energy from one form to the other, wherein the thermal energy in the thermocouple produces the thermoelectric voltage and thus is converted into electrical energy, or electrical energy is converted into thermal energy by driving the thermocouple electrically.

The thermoelectric energy converter is preferably used to detect thermal energy from the electrical energy obtained from the thermal energy. Absorption heat released in the absorption of gas molecules (see above) can thereby be used for detecting gas molecules. Thus the thermoelectric energy converter is suitable for use in gas analysis.

Thermal energy in the form of absorbed thermal radiation (heat radiation, infrared radiation) is preferably used. This means that the thermoelectric energy converter is used to detect thermal radiation. The thermoelectric energy converter acts as an infrared sensor. With a multiplicity of thermocouples connected together in series, an extremely high sensitivity of more than 1000 V per Watt of absorbed incident radiation can be achieved in this case.

In addition, the small amount of space occupied means that a high pixel count (number of image points per unit area) and hence a high spatial resolution of the thermal radiation is possible. In this case a pixel is formed by one thermocouple or a plurality of thermocouples. The high spatial resolution opens up an extremely wide range of possible applications for the thermoelectric energy converter, for instance in high-resolution infrared cameras or infrared vision equipment, in infrared scanners for thermography in medical engineering and industry or for chemical analysis.

In summary, the proposals provide the following advantages:
A large number of thermocouples per unit area are possible using the three-dimensional microstructure.
A thermal energy sensor having a high spatial resolution is attainable by the large number of thermocouples per unit area.
Thermoelectric energy converters having sensor surfaces that extend laterally can be produced. Therefore large-area, high-resolution thermal detectors are possible.
The extremely thin (down to the region of fractions of micrometers) and extremely long (up to the region of several millimeters) microcolumns result in a high sensitivity.
The microstructure comprises self-supporting microcolumns. Therefore it does not need any microstructure support surface.
Heat transfer between adjacent pixels is low, in particular when an inert gas or vacuum is used. This results additionally in increased sensitivity and increased spatial resolution.
The microcolumns can be produced in a defined and reproducible manner.
There is a large choice of materials for the microcolumn materials because of the simple process technology for filling the template cavities.
When using a circuit substrate that comprises integrated readout electronics and/or drive electronics and is connected to the microstructure substrate by flip-chip technology, the resultant lateral extent of the entire thermoelectric energy converter is not significantly larger than a surface area defined by the microstructure. A thickness of the thermoelectric energy converter is defined by the microstructure arranged on the microstructure substrate and by the circuit substrate. The thickness of the energy converter therefore equals the thickness of two stacked chips.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows a three-dimensional microstructure of a thermoelectric energy converter in a lateral cross-section.

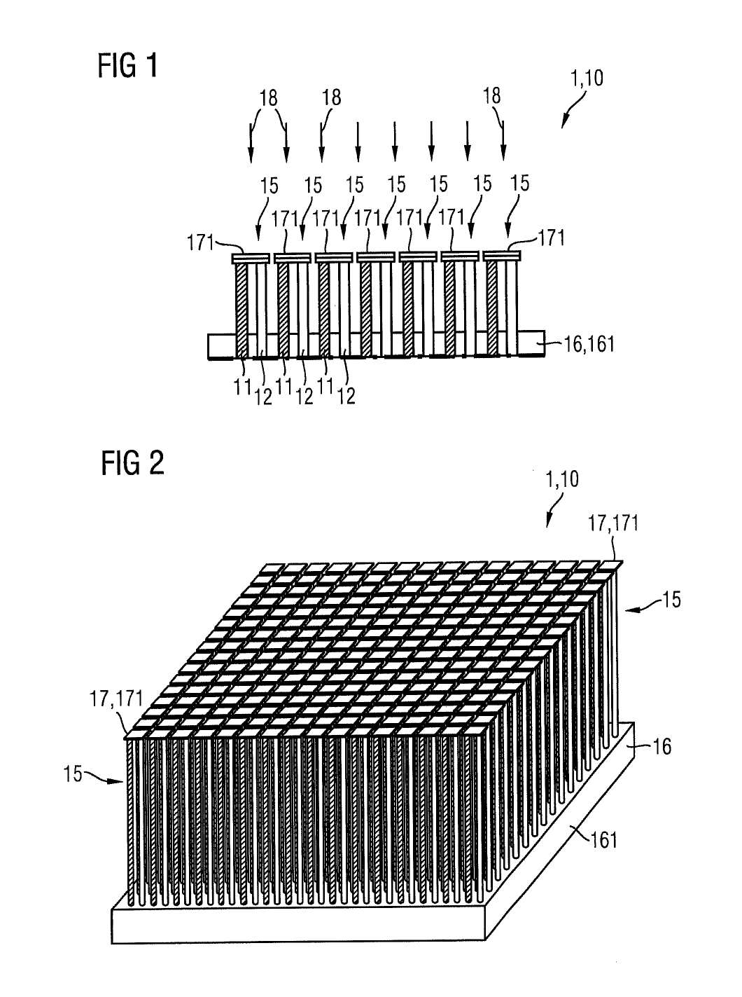

FIG. 2 shows the microstructure in a perspective view.

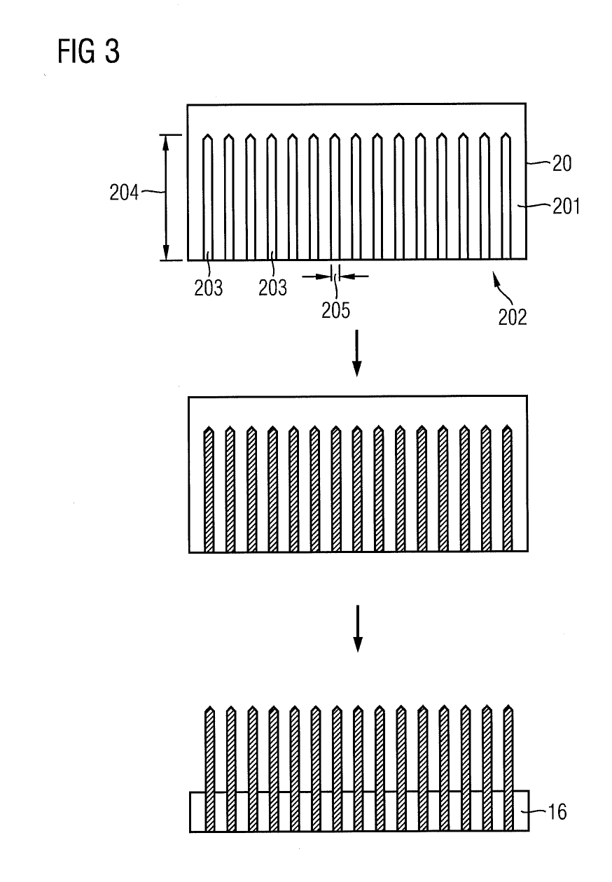

FIG. 3 shows the fundamental method for producing the microstructure.

FIG. 4 shows a method for filling template cavities in a template.

FIGS. 5A and 5B show a method for producing a thermoelectric energy converter.

FIGS. 6A and 6B show a method for producing a further thermoelectric energy converter.

FIGS. 7A and 7B show a method for making contact between the microstructure substrate and a circuit substrate comprising readout electronics.

FIG. 8 shows a detail of a thermocouple comprising microcolumns arranged side by side.

FIG. 9 shows a detail of a thermocouple comprising microcolumns arranged one above the other.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

The subject of each of the following examples is a thermoelectric energy converter 1 for converting thermal energy and electrical energy. The energy converter operates on the principle of the Seebeck effect. The thermoelectric energy converter is embodied as an infrared sensor for detecting thermal radiation 18.

The energy converter has at least one self-supporting, three-dimensional microstructure 10. The microstructure 10 comprises a multiplicity of thermocouples 15 for building up a thermoelectric voltage. The thermocouples are connected in series so that the thermoelectric voltages from the individual thermocouples are summated.

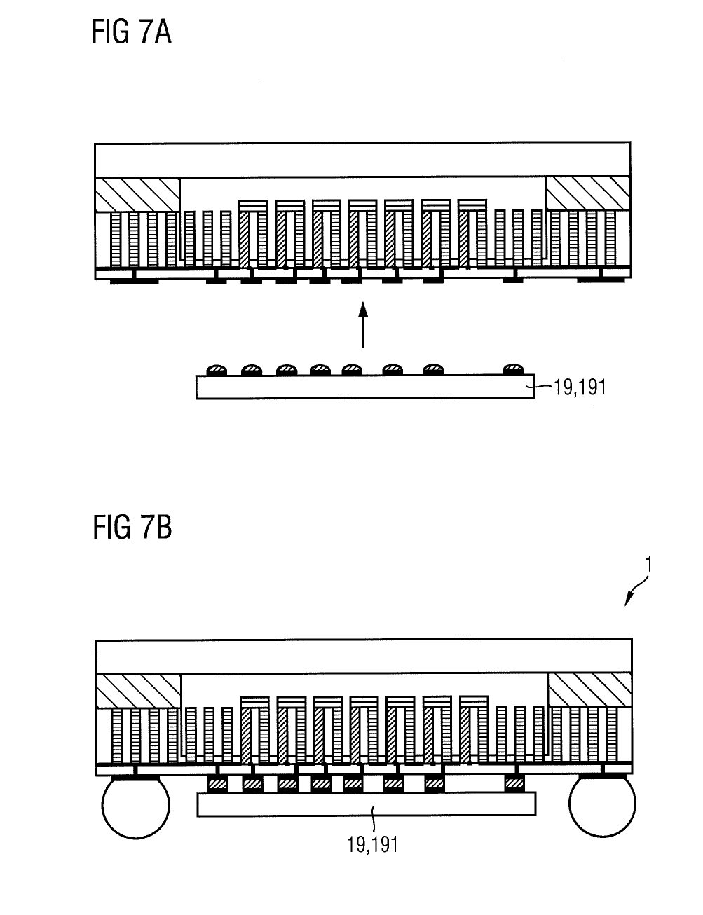

Each of the thermocouples comprises at least one self-supporting microcolumn 11, which has a first microcolumn longitudinal extent 111, a first microcolumn diameter 112 and at least one first microcolumn material 110 having a first thermopower (FIG. 8). The first microcolumn material is bismuth telluride (Bi₂Te₃).

Each of the thermocouples also has at least one second self-supporting microcolumn 12, which has a second microcolumn longitudinal extent 121, a second microcolumn diameter 122 and at least one second microcolumn material 120 having a second thermopower that differs from the first microcolumn material. The second microcolumn material is elemental molybdenum.

The longitudinal extents of the microcolumns are arranged substantially parallel to one another. The microcolumn diameters equal approximately 0.3 μm and the microcolumn longitudinal extents equal 120 μm. Thus the aspect ratio of each of the microcolumns equals approximately 400.

An interstitial space 14 exists between adjacent microcolumns. The microcolumn interstitial space has a microcolumn spacing 141 between adjacent microcolumns in the region of approximately 0.3 μm.

In one embodiment variant, an inert gas is arranged in the microcolumn interstitial space. In an alternative embodiment variant thereto, the microcolumn interstitial space is evacuated. The inert gas or the vacuum in the interstitial space acts as mechanism 142 for thermally isolating the microcolumns from one another.

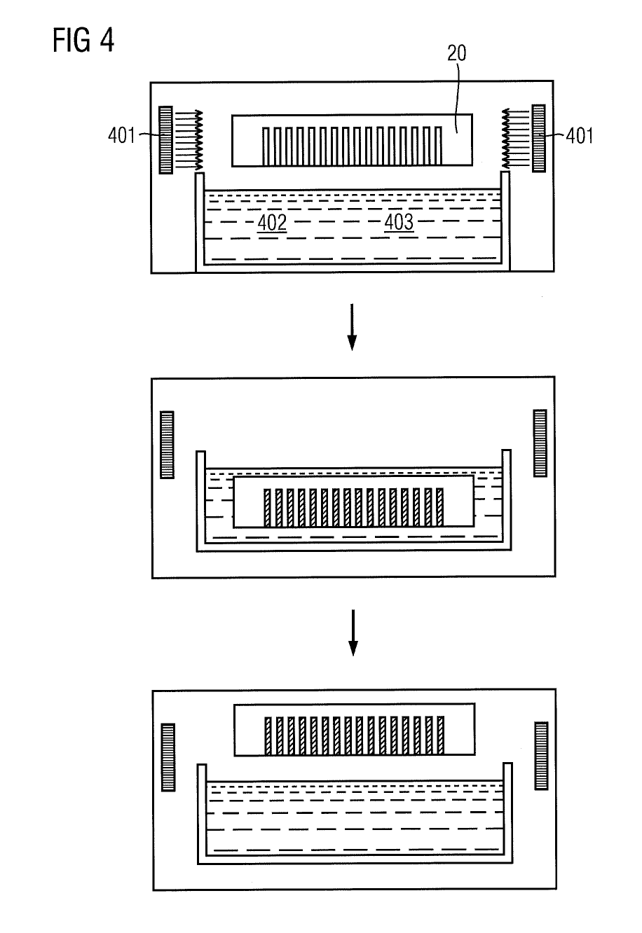

The microstructure is joined to a microcolumn substrate 16 which is obtained from the used template 20 by partial removal of the template material 201 (FIG. 3). The substrate material 161 of the microcolumn substrate is the template material of the template. In an alternative embodiment variant, the microstructure remains on a microcolumn substrate that has been joined to the template during the production process. The template material is removed entirely. What is left is the microstructure on the substrate.

The following steps are carried out to produce the three-dimensional microstructure: a) providing a template comprising template material, the template having a three-dimensional template structure that is substantially the inverse of the microstructure of the thermoelectric energy converter and comprises columnar template cavities, b) arranging the microcolumn materials in the columnar cavities so as to produce the microcolumns, and c) removing the template material at least partially (FIG. 3). The following additional method are carried out in order to arrange the microcolumn materials: d) introducing starting material for at least one of the microcolumn materials into the cavities, and e) converting the starting material of the microcolumn material into the microcolumn material.

The starting point is a silicon wafer. This silicon wafer acts as the template. The template material 201 is silicon. The PAECE process is used to form the template cavities 203 into the silicon wafer. The template cavities are formed with a cavity longitudinal extension 204 and cavity diameter 205 that correspond to the microcolumns to be produced. The spacings between the template cavities are also chosen to correspond to the microcolumn spacings. The template structure 202 is produced.

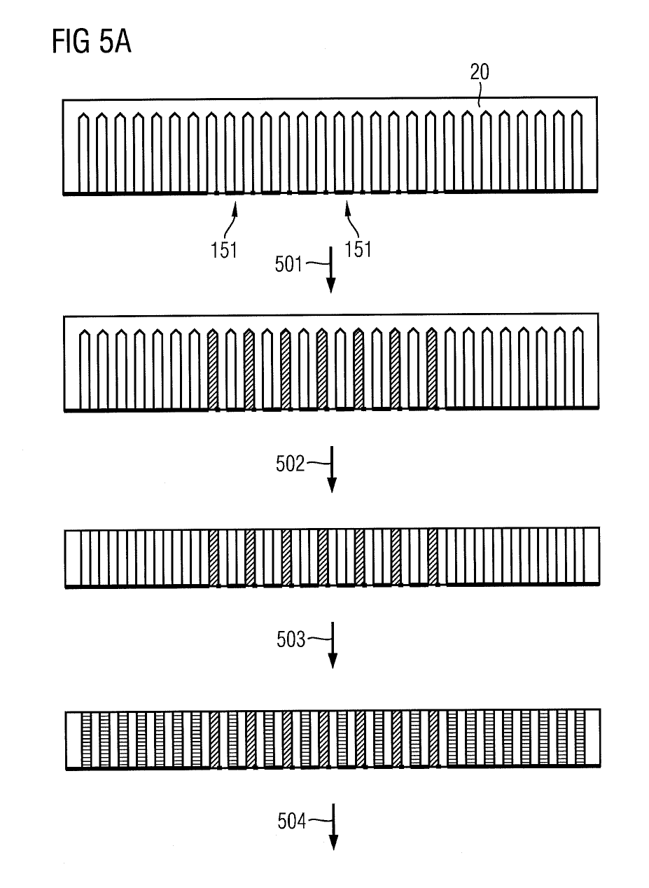

Next the columnar template cavities are filled with liquid microstructure material. This process is illustrated by way of example in FIG. 4: the template comprising template cavities is heated by the heating elements 401 and dipped in a tank 402 containing liquid metal 403. Varying an external pressure ensures that the liquid metal penetrates into the template cavities. Then the template containing the filled template cavities is removed from the tank. The template cools, resulting in solidification of the metal in the template cavities. The microcolumns are produced from the metal. The liquid metal acts as the starting material for the microstructure material. It is transformed into the microstructure material (solid metal) by cooling.

### EXAMPLE 1

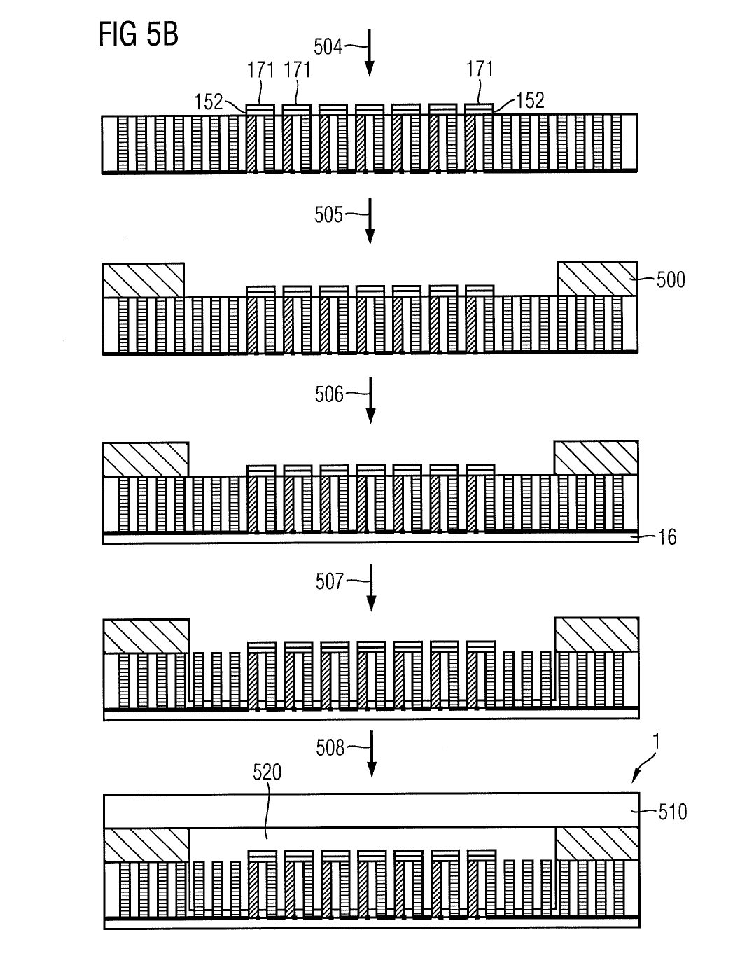

After passivation and the PAECE process, the “cold junctions” 151 of the thermocouples are produced (FIGS. 5A and 5B).

A liquid starting material for the first microcolumn material is subsequently introduced into some of the template cavities (step 501). The first microcolumn material has a higher melting point than the second microcolumn material. The first microcolumns are produced.

After removing template material from the other side of the template and planarization (step 502), the second microcolumns are arranged in the remaining template cavities (503).

Then the hot junctions 152 of the thermocouples are produced. In addition, an absorption layer 171 for the thermal radiation to be detected is also deposited for each contact (step 504).

In the next step 505, a spacer 500 is arranged on the microstructure. Optionally, a microstructure substrate 16 or a terminating layer is also arranged (step 506).

Then, in an etching step, template material is removed from the template (step 507). Silicon is removed from the silicon wafer used as the template.

Finally, an infrared window 510 is deposited, which is transparent to the thermal radiation to be detected. In addition, the resultant internal space 520 is evacuated. The internal space is bounded by the microstructure, the spacer and the infrared window. The microcolumn interstitial spaces of the microstructure are evacuated as a result of the evacuation.

### EXAMPLE 2

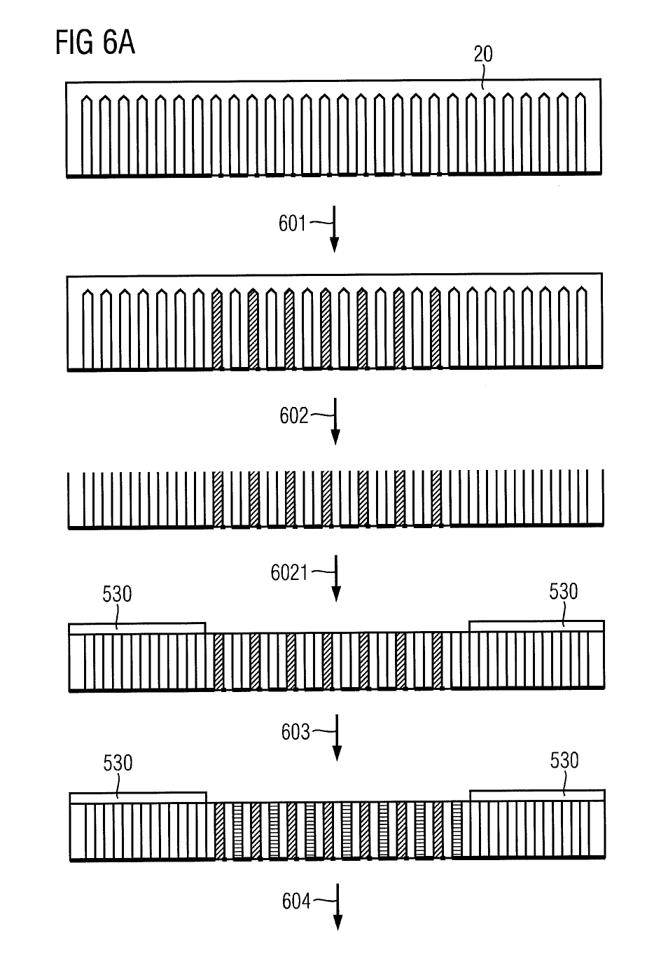

Steps 601 to 606 and 608 of Example 2 (FIGS. 6A and 6B) are identical and correspond to steps 501 to 506 and 508 of Example 1. Unlike Example 1, after arranging the first microcolumns, a frame 503 is deposited in step 6021. The frame covers some of the template cavities that have not been filled yet. These template cavities remain empty for the rest of the process, i.e. are not filled.

A further difference appears in step 607: that part of the frame 503 that is not covered by the spacer is removed in the silicon etching process. This results in a larger internal space to be evacuated later in the subsequent process.

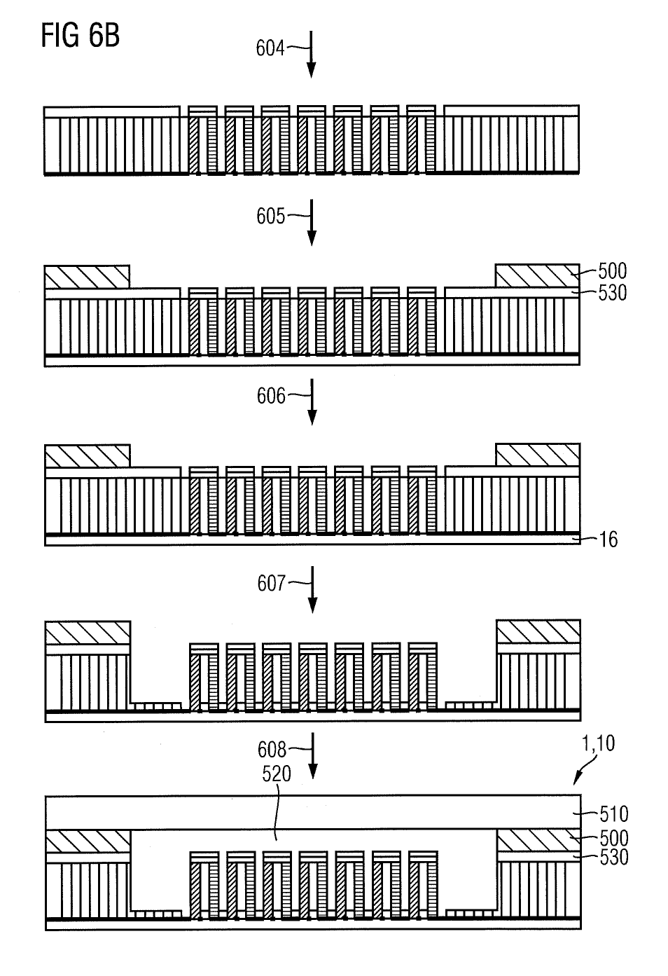

Connecting the microstructure substrate to a circuit substrate 19, in other words making electrical contact between a readout device 191 integrated as an ASIC in the circuit substrate and the thermocouples of the microstructure, forms the final stage. This is shown in FIGS. 7A and 7B. The microstructure substrate and the circuit substrate are connected together using flip-chip technology. In this case, electrical contacting is realized from the rear face of the thermoelectric energy converter. Thus no shadow is cast on any of the thermally sensitive elements of the energy converter.

### EXAMPLE 3

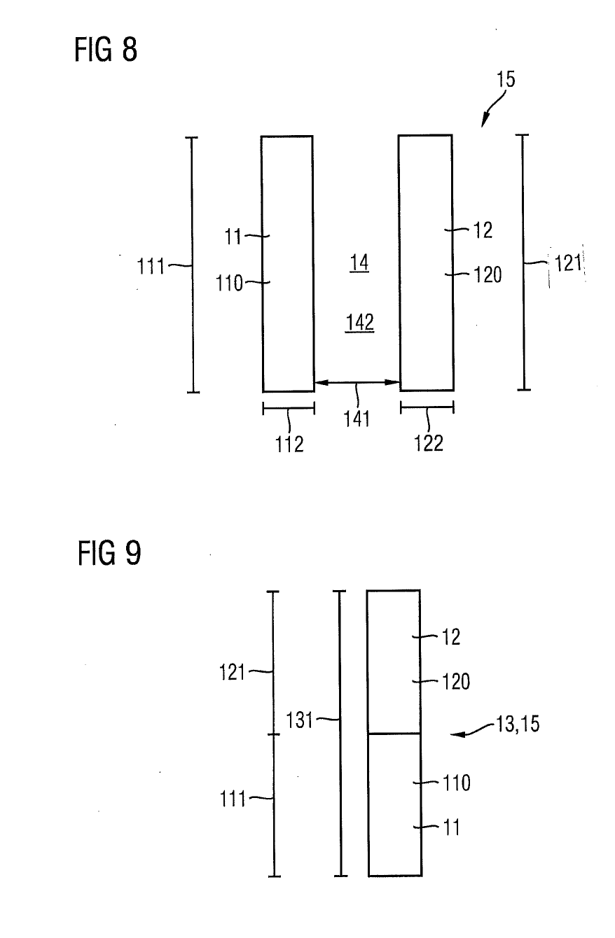

Unlike the previous examples, the first and the second microcolumns of a thermocouple are not arranged side by side but one above the other to form a total microcolumn 13 having a total microcolumn longitudinal extent 131 (FIG. 9). A total microcolumn diameter equals the microcolumn diameters of the first and second microcolumns. The thermoelectric energy converter comprises a multiplicity of such total microcolumns.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide V. DIRECTV, 69 USPQ2d 1865 (Fed. Cir. 2004).

1-23. (canceled)

24. A thermoelectric energy converter to convert thermal energy into electrical energy and/or vice versa, comprising:
at least one self-supporting, three-dimensional microstructure comprising:
a plurality of first microcolumns having a first microcolumn longitudinal extent, a first microcolumn diameter and being formed from a first microcolumn material having a first thermopower; and
a plurality of second microcolumns having a second microcolumn longitudinal extent, a second microcolumn diameter and being formed from a second microcolumn material having a second thermopower that is different from the first microcolumn material, wherein
the first and second microcolumns are positioned such that the first and second longitudinal extents are substantially parallel to one another,
the first and second microcolumn diameters are within a range of from 0.1 μm to 200 μm,
the first and second microcolumns each have an aspect ratio in a range of from 20 to 1000, and
the first and second microcolumns are coupled together as a thermocouple to convert thermal energy into electrical energy and/or vice versa.

25. The thermoelectric energy converter as claimed in claim 24, wherein at least one of the first microcolumn material and the second microcolumn material is selected from the group consisting of bismuth, antimony, tellurium, lead and compounds thereof.

26. The thermoelectric energy converter as claimed in claim 24, wherein the first and second microcolumn diameters are selected from a range of from 0.3 μm to 200 μm.

27. The thermoelectric energy converter as claimed in claim 24, wherein the first microcolumns are arranged linearly above the the second microcolumns to form total microcolumns having a total longitudinal extent equal to a sum of the first and second microcolumn longitudinal extents.

28. The thermoelectric energy converter as claimed in claim 27, wherein the total microcolumn longitudinal extent is within a range of from 50 μm to 10 mm.

29. The thermoelectric energy converter as claimed in claim 24, wherein the first and/or second microcolumn longitudinal extent is within a range of from 50 μm to 10 mm.

30. The thermoelectric energy converter as claimed in claim 24, wherein the first and second microcolumn longitudinal extents are within a range of from 100 82 m to 1 mm.

31. The thermoelectric energy converter as claimed in claim 24, wherein the first and second microcolumns are arranged side by side such that a microcolumn interstitial space results between adjacent first and second microcolumns, and the microcolumn interstitial space has a microcolumn spacing in a range of from 0.3 μm to 100 μm.

32. The thermoelectric energy converter as claimed in claim 24, wherein the first and second microcolumns are arranged side by side such that a microcolumn interstitial space results between adjacent first and second microcolumns, and the converter further comprises a thermal isolator arranged in the microcolumn interstitial space between adjacent microcolumns.

33. The thermoelectric energy converter as claimed in claim 32, wherein the thermal isolator is a vacuum having a gas pressure of less than 10⁻² mbar.

34. The thermoelectric energy converter as claimed in claim 24, wherein each of the at least one microstructure comprises at least one thermal coupling mechanism to couple thermal energy into and/or out of the energy converter.

35. The thermoelectric energy converter as claimed in claim 34, wherein the thermal coupling mechanism comprises a thermal functional layer to absorb and/or emit thermal radiation.

36. The thermoelectric energy converter as claimed in claim 24, wherein the the first and second microcolumns are arranged on a common microstructure substrate.

37. The thermoelectric energy converter as claimed in claim 24, further comprising:
a readout device to read out a thermoelectric voltage of the thermocouple; and/or
a drive device to drive the thermocouple with a drive voltage.

38. The thermoelectric energy converter as claimed in claim 37, wherein
the first and second microcolumns are arranged on a common microstructure substrate, and
the readout device and/or the drive device are integrated into the microstructure substrate.

39. The thermoelectric energy converter as claimed in claim 37, wherein
the first and second microcolumns are arranged on a common microstructure substrate, and
the readout device and/or the drive device are integrated into a circuit substrate different from the microstructure substrate.

40. The thermoelectric energy converter as claimed in claim 39, wherein the microstructure substrate and the circuit substrate are connected together via flip-chip technology.

41. The thermoelectric energy converter as claimed in claim 24, wherein
the thermoelectric energy converter comprises a multiplicity of thermocouples, and
the thermocouples of the multiplicity of thermocouples are connected together in series so that a total thermoelectric voltage is produced from a sum of individual thermoelectric voltages of the thermocouples.

42. A method for producing a thermoelectric energy converter to convert thermal energy into electrical energy and/or vice versa, comprising:
providing a template formed of a template material, the template having a three-dimensional template structure that is substantially an inverse of a three-dimensional microstructure comprising a plural first and plural second microcolumns respectively having substantially parallel microcolumn longitudinal extents, having first and second microcolumn diameters within a range of from 0.1 μm to 200 μm, and having aspect ratios in a range of from 20 to 1000, the three-dimensional template structure comprising columnar template cavities;
inserting first and second microcolumn materials into the columnar cavities so as to respectively produce the first and second microcolumns, the first and second microcolumn materials having first and second different thermopowers; and
removing at least a portion of the template material.

43. The method as claimed in claim 42, wherein inserting the first and second microcolumn materials comprises:
introducing first and second starting materials into the cavities; and
converting the first and second starting materials respectively into the first and second microstructure materials.

44. The method as claimed in claim 42, wherein silicon is used as the template material.

45. The method as claimed in claim 42, wherein the template has a microstructure substrate for the microstructure.

46. A method comprising:
providing at least one self-supporting, three-dimensional microstructure comprising:
a plurality of first microcolumns having a first microcolumn longitudinal extent, a first microcolumn diameter and being formed from a first microcolumn material having a first thermopower; and
a plurality of second microcolumns having a second microcolumn longitudinal extent, a second microcolumn diameter and being formed from a second microcolumn material having a second thermopower that is different from the first thermocouple material, wherein
the first and second microcolumns are positioned such that the first and second longitudinal extents are substantially parallel to one another,
the first and second microcolumn diameters are within a range of from 0.1 μm to 200 μm,
the first and second microcolumns each have an aspect ratio in a range of from 20 to 1000, and
the first and second microcolumns are coupled together as a thermocouple to produce a thermoelectric voltage; and
converting thermal energy received at the thermocouple into electrical energy having a thermoelectric voltage and/or electrically driving the thermocouple to convert electrical energy into thermal energy.

47. The use as claimed in claim 46, wherein
thermal energy received at the thermocouple is converted into electrical energy, and
the electrical energy is used to detect the thermal energy.

48. The use as claimed in claim 47, wherein thermal energy is absorbed thermal radiation.
